(19) United States
(12) Patent Application Publication
(10) Pub. No.: US 2010/0230673 A1
(43) Pub. Date: Sep. 16, 2010

(54) Semiconductor Fuse Structure and a Method of Manufacturing a Semiconductor Fuse Structure

(75) Inventors: Claire Ravit, Louvain (BE); Tobias S. Doorn, Eindhoven (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/303,710

(22) PCT Filed: Jun. 6, 2007
(86) PCT No.: PCT/IB2007/052125

§ 371 Date: Dec. 5, 2008

(30) Foreign Application Priority Data
Jun. 9, 2006 (EP) 06115191.6

(51) Int. Cl. H01L 23/525; H01L 21/18; H01L 21/768

(52) U.S. Cl. 257/49; 438/514; 438/601; 257/529; 257/E23.149; 257/E21.592; 257/E21.085

(57) ABSTRACT

The invention relates to a semiconductor fuse structure comprising a substrate (1) having a surface, the substrate (1) having a field oxide region (3) at the surface, the fuse structure further comprising a fuse body (FB), the fuse body (FB) comprising polysilicon (PLY), the fuse body (FB) lying over the field oxide region (3) and extending into a current-flow direction (CF), wherein the fuse structure is programmable by means of leading a current through the fuse body (FB), wherein the fuse body (FB) has a tensile strain in the current-flow direction (CF) and a compressive strain in a direction (Z) perpendicular to said surface of the substrate (1). The invention further relates to methods of manufacturing such a semiconductor fuse.

The invention relates to a semiconductor fuse structure comprising a substrate having a surface, the substrate having a field oxide region at the surface, the fuse structure further comprising a fuse body, the fuse body comprising polysilicon, the fuse body lying over the field oxide region and extending into a current-flow direction, wherein the fuse structure is programmable by means of leading a current through the fuse body.

The invention also relates to an integrated circuit comprising such a semiconductor fuse structure.

The invention further relates to methods of manufacturing a semiconductor fuse structure.

Fuses for semiconductors have a wide range of applications such as die-ID, redundancy in memories, encryption, etc. Polysilicon fuses are rapidly replacing laser fuses, because they can be programmed electrically, which reduces programming costs and increases flexibility. Polysilicon fuses are currently being replaced by silicided polysilicon fuses for reducing their non-programmed resistance. These silicided polysilicon fuses are fabricated using standard CMOS processes. A large resistance after programming is desirable for easy state-detection, while fast programming is essential for short test and repair times. Furthermore, it is desirable that the programming voltage polysilicon fuses is as low as possible, so that no special measures are necessary to integrate these fuses into an integrated circuit. In general, the programming time increases when the programming voltage is reduced.

A drawback of the known polysilicon fuses is that their programming voltage is still relatively high.

It is an object of the invention to provide a semiconductor fuse structure which has a lower programming voltage while still maintaining the same programming time, or which has a shorter programming time while maintaining the same programming voltage.

The invention is defined by the independent claims. The dependent claims define advantageous embodiments.

The object of the invention is realized in that the fuse body has a tensile strain in the current-flow direction and a compressive strain in a direction perpendicular to said surface of the substrate. Because of the tensile strain in the current-flow direction and the compressive strain in the direction perpendicular to the surface of the substrate the electron mobility increases. The increased electron mobility leads to an increased electromigration, which in its turn leads to faster breakdown of the fuse. The faster breakdown of the fuse can then be exploited to reduce the programming voltage. Alternatively, when the programming voltage is kept the same, the programming time is reduced.

The semiconductor device according to the invention provides an additional advantage. Process-induced strain techniques are nowadays being explored to enhance carrier mobility in MOSFET devices and thus boost device performance. Thus the implementation of process-induced strain techniques in polysilicon fuses is very likely to be compatible with the future CMOS processes.

In an advantageous embodiment of the fuse structure according to the invention the fuse body comprises a first sublayer and a second sublayer, the first sublayer comprising polysilicon, the first sublayer lying over the field oxide region, the second sublayer comprising a silicide, the second sublayer lying over the first sublayer. This fuse structure has a dual-layer structure and is advantageous because of its lower resistance (because of the low-resistive silicide) before programming, which reduces the required programming voltage.

In another embodiment of the fuse structure according to the invention a tensile-strain layer at least covers both the fuse body and part of the substrate, so as to form the compressive strain in the fuse body in the direction perpendicular to said surface. The presence of this strain layer ensures that the strain in the fuse body is maintained better. Furthermore, during manufacturing of the fuse structure the strain layer can be used as a contact etch stop layer (CESL).

The invention also relates to an integrated circuit comprising such a semiconductor fuse structure. Scaling of CMOS processes also means reducing supply voltage and reducing I/O-voltages. The lower programming voltage of the fuse structure according to the invention thus provides better integration possibilities into future CMOS processes. Thus, an integrated circuit manufactured in these processes can greatly benefit from the reduced programming voltage of the fuse structure. A lower programming voltage reduces the need for special measures which make it possible to program the fuse structure (like the introduction of special high-voltage transistors) and thus the complexity of the integrated circuit is reduced.

The invention further relates to a method of manufacturing a semiconductor fuse structure. A first method according to the invention comprises the following steps of:

providing a substrate having a surface, the substrate comprising a field oxide region at the surface;

providing a first layer comprising polysilicon at least on the field oxide region;

patterning the first layer for at least forming a fuse body on the field oxide region, the fuse body extending into a current-flow direction;

performing an amorphization implant on the first layer for converting the polysilicon of at least the fuse body into amorphous silicon;

covering the substrate and the fuse body with a strain layer, wherein the strain layer is a low strain or tensile strain layer which results in a compressive strain in the fuse body in a direction perpendicular to the surface and which further results in a tensile strain in the fuse body in the current-flow direction;

performing a spike-anneal such that the amorphous silicon in the fuse body is recrystallised into polysilicon with preservation of at least part of its strain; and

providing spacers on both sidewalls of the fuse body.

The method of manufacturing according to the invention provides a convenient way of forming a semiconductor fuse structure according to the invention. A layer with a low strain is typically in the −200 to 200 MPa range. It may then be a low tensile strain or a low compressive strain. A low strain layer is also suitable as any nitride layer becomes tensile strained upon annealing. Thus, a low strain layer will turn into a tensile strain layer during the thermal budget of subsequent CMOS process steps. The technique of amorphization, followed by straining and recrystallisation with preservation of strain, is also called a “Stress Memorization Technique”.

One embodiment of the method according to the invention is characterized in that the strain layer is removed prior to the step of providing spacers. This step makes it possible to form the spacers in a more conventional way.

In an advantageous variant of the method according to the invention the method comprises a step of forming a silicide on the fuse body before the step of covering the substrate and the fuse body with a strain layer or after removal of the strain layer. This variant is advantageous, because the resulting fuse structure is a dual-layer structure and is advantageous because of its lower resistance (because of the low-resistive silicide) before programming, which reduces the required programming voltage.

A second method according to the invention comprises the following steps of:

providing a substrate having a surface, the substrate comprising a field oxide region at the surface;

providing a first layer comprising polysilicon at least in the field oxide region;

patterning the first layer for at least forming a fuse body in the field oxide region, the fuse body extending into a current-flow direction;

providing spacers on both sidewalls of the fuse body; and

covering the substrate, the fuse body and the spacers with a strain layer, wherein the strain layer is a tensile strain layer which results in a compressive strain in the fuse body in a direction perpendicular to the surface and which further results in a tensile strain in the fuse body in the current-flow direction.

This method of manufacturing according to the invention provides an alternative way of forming a semiconductor fuse structure according to the invention. The advantage of the second method is that it is less complex (it requires fewer process steps).

Preferably, the method comprises a step of forming a silicide on the fuse body, prior to the step of covering the substrate, the fuse body and the spacers with the strain layer. This variant of the method is advantageous, because the resulting fuse structure is a dual-layer structure and is advantageous because of its lower resistance (because of the low-resistive silicide) before programming, which reduces the required programming voltage.

Any of the additional features can be combined together and combined with any of the aspects. Other advantages will be apparent to those skilled in the art. Numerous variations and modifications can be made without departing from the scope of the claims of the present invention. Therefore, it should be clearly understood that the present description is illustrative only and is not intended to limit the scope of the present invention.

How the present invention may be put into effect will now be described by way of example with reference to the appended drawings, in which:

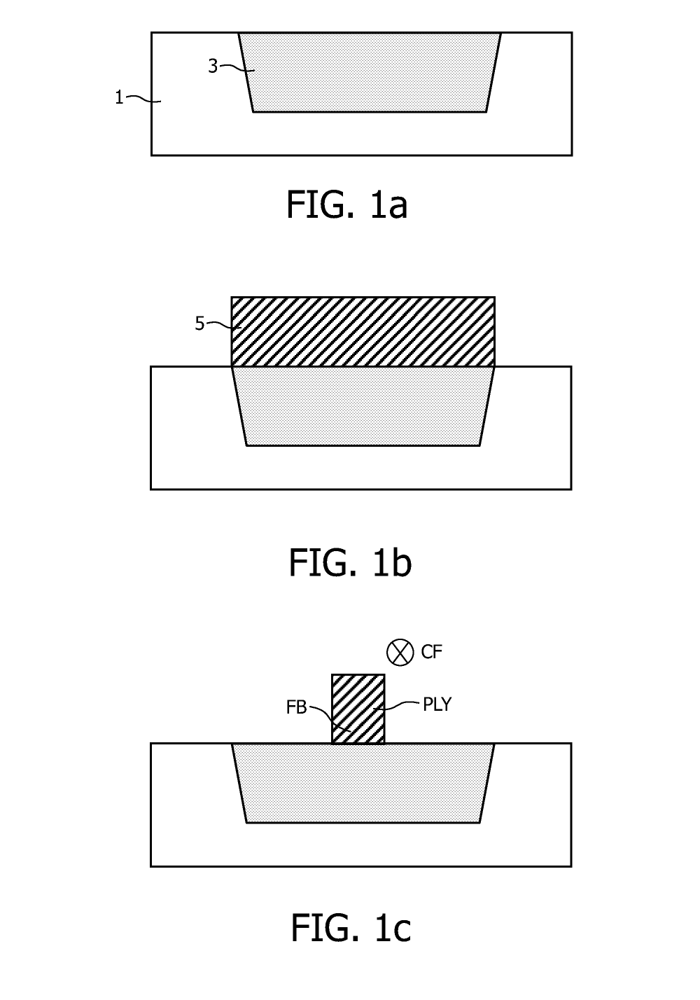

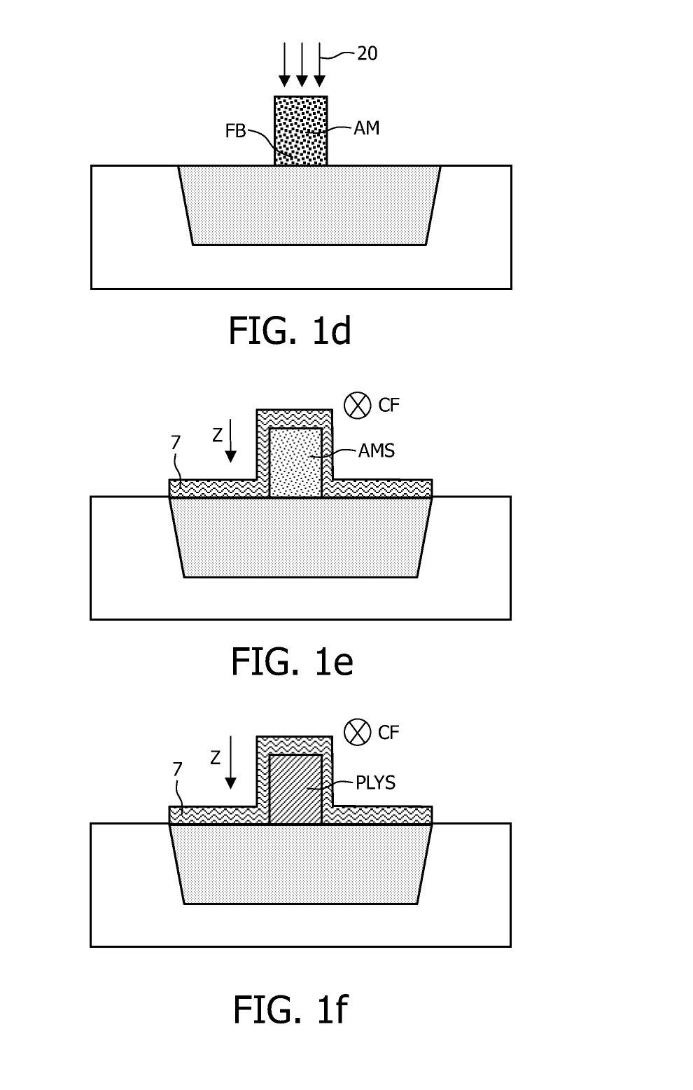

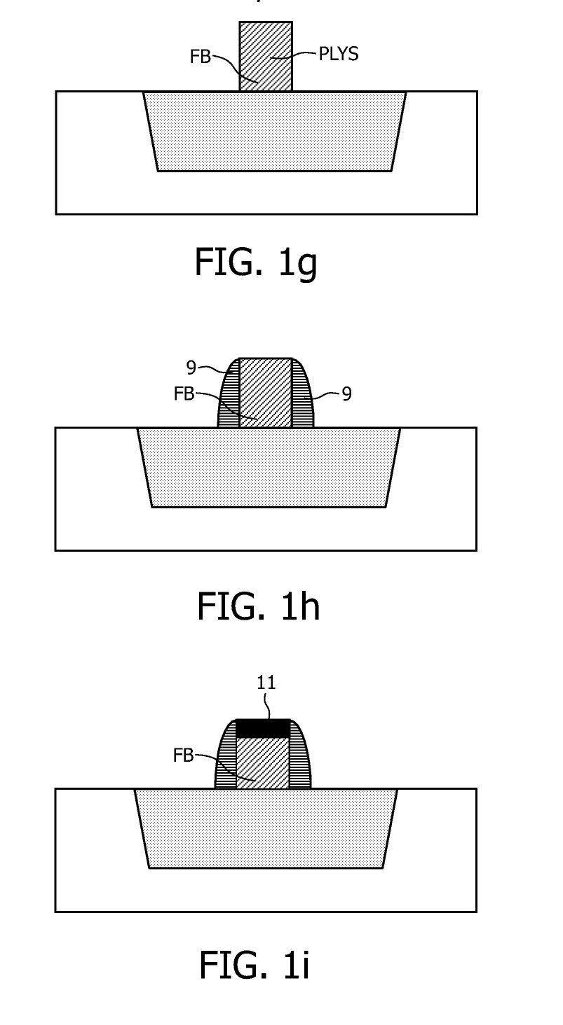

FIGS. 1a-1i illustrate different stages of a first method of manufacturing a fuse structure according to the invention;

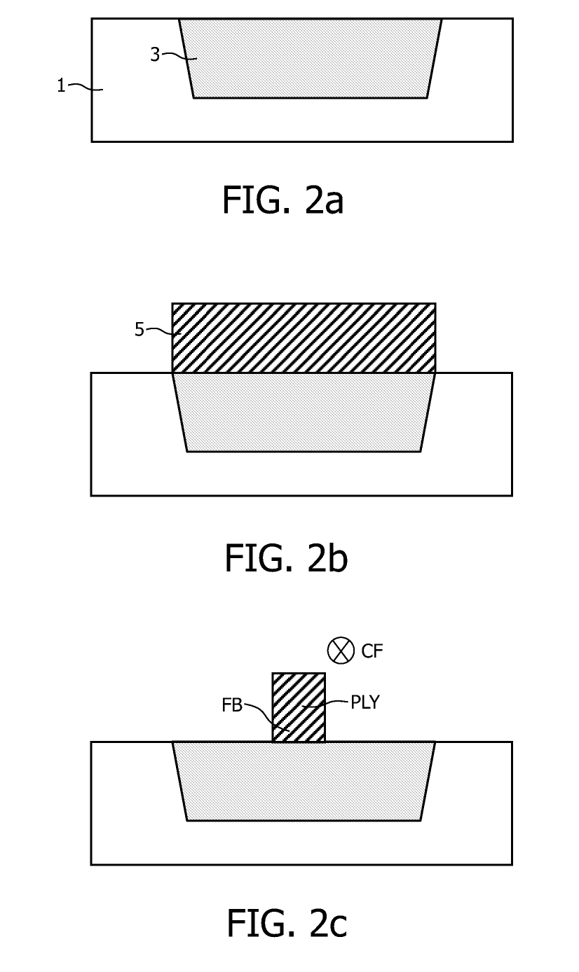

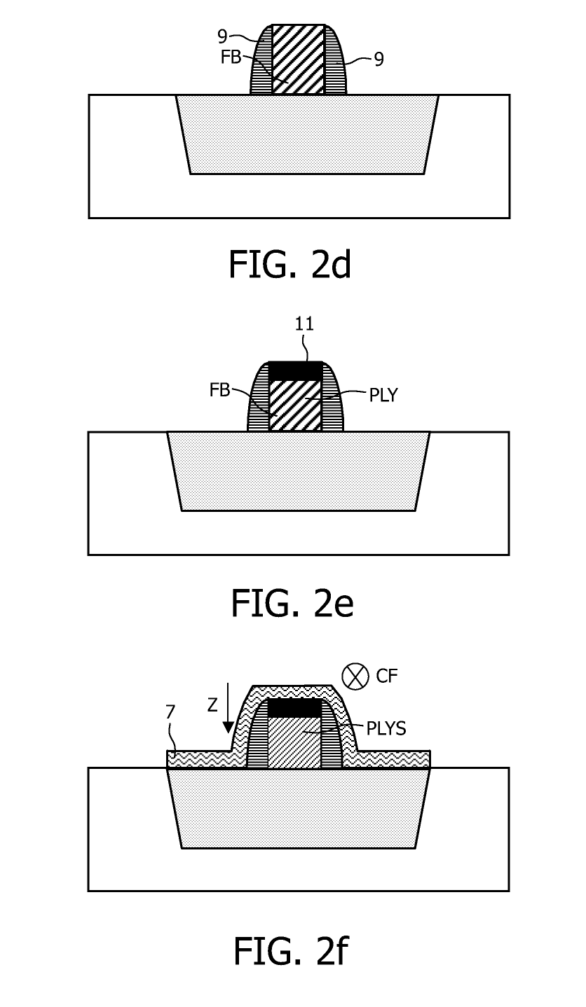

FIGS. 2a-2f illustrate different stages of a second method of manufacturing the fuse structure according to the invention;

FIG. 3 illustrates a schematic cross-section of a silicided polysilicon fuse structure having a contact; and

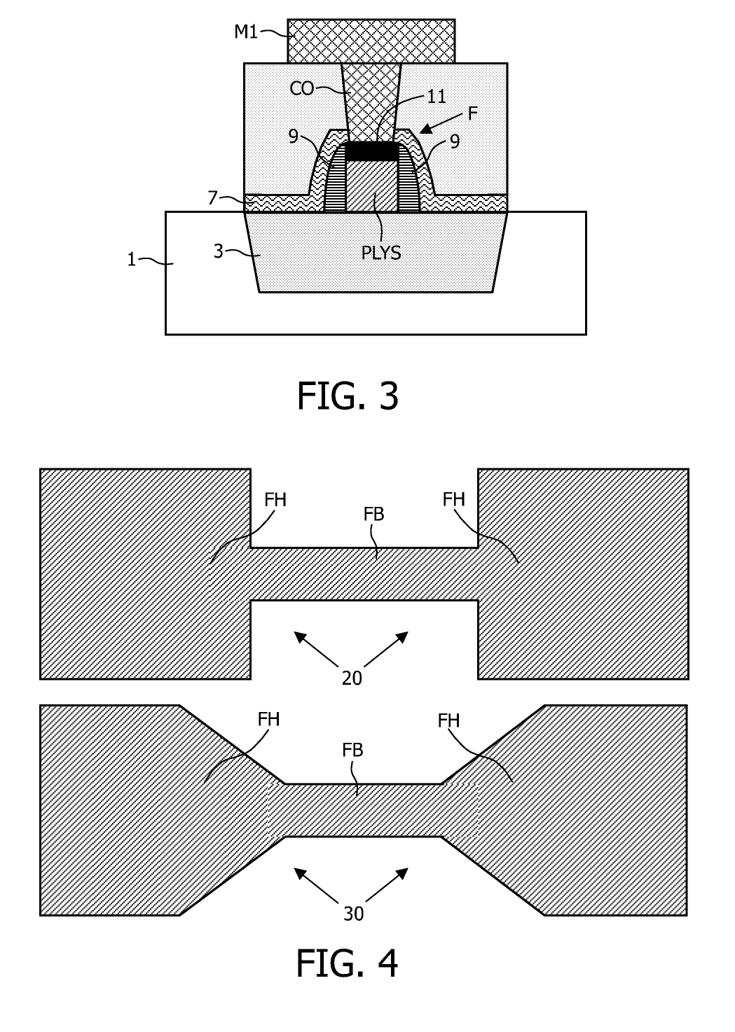

FIG. 4 illustrates two different shapes of the fuse structure according to the invention.

Referring to FIGS. 1a-1i, these Figures illustrate different stages of a first method of manufacturing a fuse structure according to the invention. In the stage illustrated in FIG. 1a a substrate 1 is provided. The substrate comprises a field oxide region 3. Field oxide regions define those regions on a substrate where no transistors should be created. Or worded differently, field oxide regions isolate individual transistors (not shown in Figures) from each other. The substrate may comprise various materials (silicon, germanium, III-V compounds, etc) and can be of any type. For example: bulk substrates, silicon-on-insulator substrates (SOI), The field oxide region 3 can be a so-called shallow trench isolation region (STI-region), a so-called LOCOS region, or any other type of insulating region.

In another stage of the first method (FIG. 1b) a first layer comprising polysilicon 5 is deposited at least in the field oxide region 3. Layer deposition techniques are common general knowledge of the person skilled in the art.

In a further stage of the first method (FIG. 1c) the first layer 5 is patterned (using known lithographic techniques) so that a fuse body FB is formed. In this particular example the fuse body FB comprises polysilicon PLY. The fuse body FB extends into a current-flow direction CF. The current-flow direction CF is defined by the direction in which the current flows (ignoring possible cross-sectional variations of the fuse body like notches, holes, etc) when the fuse structure is being programmed. The fuse body FB may be connected to fuse heads (not shown) and the fuse heads may be connected via interconnect to circuitry (not shown). Technically, it is possible to form the fuse body together with transistor gates (not shown) located outside the field oxide regions.

In a further stage of the first method (FIG. 1d) an amorphization implant 20 is performed to amorphize the polysilicon of the fuse body. Amorphization techniques are known to the person skilled in the art, for example in “Silicon Processing for the VLSI Area”, Vol. 1—Process Technology, p. 390. For the amorphization ions 20 such as Arsenic (As) and Germanium (Ge) can be used. During the amorphization implant 20 the polysilicon PLY in the fusebody FB is converted into amorphous silicon AM.

In another stage of the first method (FIG. 1e) a thin oxide layer (not shown) is provided (for example using deposition techniques). This thin oxide layer may comprise for example silicon oxide. The deposition of the oxide layer is optional. However, the etch selectivity could be degraded when removing the strain layer in a later stage of the method. In this example the thickness of the thin oxide layer is between 1-10 nm, but another thickness is also possible. After the deposition of the thin oxide layer a low strain or a tensile strain layer 7 is deposited. A layer with a low strain is typically in the −200 to 200 MPa range. It can then be a low tensile strain or a low compressive strain. A low strain layer is also suitable as any nitride layer becomes tensile strained upon annealing. Thus, a low strain layer will turn into a tensile strain layer during the thermal budget of subsequent CMOS process steps. The strain layer 7 can be a silicon nitride layer and the strain may be larger than 500 MPa. In this example the thickness of the strain layer 7 may be around 50 nm for example, but another thickness is also possible. The layers should be deposited at low temperature to avoid poly-recrystallisation during the deposition, preferably at a temperature below 500° C. It could be a PECVD deposition technique for example. The strain layer 7 induces a compressive strain in a vertical direction Z perpendicular to the substrate 1 and a tensile strain in a direction parallel to the fuse body, from now on being referred to as the current flow direction CF. In other words, the amorphous silicon AM changes into strained amorphous silicon AMS. The strain in the fuse body FB is beneficial to the electron mobility, see also H. Irie et al., “In-plane mobility anisotropy and universality under uni-axial strains in n- and p-MOS inversion layers on (100), (110) and (111) Si”, IEDM Tech. Dig., 2004, p. 225-228.

In a further stage of the first method (FIG. 1f) a spike-anneal step is performed. This can be done at a temperature of 1000° C. during a very short time, preferably very close to 0 s. In the exemplary anneal step, the temperature is chosen between 1000° C. and 1200° C. for a period of between 0 and 2 seconds. Alternatively, an anneal step at 950° C. of 30 seconds may also work. It belongs to the normal skills of the skilled person to find the ideal conditions for the spike-anneal step. During the spike-anneal, the polysilicon is recrystallised in the original strained state. In other words, the compressive strain in the vertical direction Z and tensile strain in the current flow direction CF are at least partially maintained. The strained amorphous silicon AMS has changed into strained polysilicon PLYS.

In a later stage of the first method (FIG. 1g) the strain layer 7 is removed. This removal can be easily done selectively in case a thin oxide layer (see description of FIG. 1e) is present below the strain layer. In that case the strain layer 7, which comprises nitride for example, can be selectively removed with respect to the underlying oxide. Finally, the thin oxide layer can be removed with carbon fluoride etchant (HF) for example. In case no oxide layer has been deposited below the strain layer 7, it will be more difficult to remove the strain layer 7, because the removal requires a good selectivity towards oxide, poly and silicon.

In a further stage of the first method (FIG. 1h) spacers 9 are formed on sidewalls of the fuse body FB. The spacers 9 can be made of silicon oxides, silicon nitrides, polymers or other insulating materials. The provision of spacers is well known to the person skilled in the art.

Alternative to the steps in FIGS. 1g and 1h, it is also possible to form spacers 9 directly from the strain layer by means of a dry etch or an anisotropic etch of the strain layer 7.

Yet in another stage of the first method (FIG. 1i) the fuse body FB of the polysilicon fuse is provided with a silicide 11, also being referred to as silicidation. The silicide 11 can for example be cobalt silicide, titanium silicide, nickel-silicide, nickel-platinum silicide or another silicide. The formation of a silicide 11 on the fuse body FB results in a so-called dual-layer or bi-layer fuse, and silicided polysilicon fuse in this particular example. When the silicide 11 is left out, a single-layer polysilicon fuse is formed. The provision of silicides is well known to the person skilled in the art. It must be noted that the moment of forming the silicide is not bound to one place in the method.

The technique illustrated in FIGS. 1a to 1i is also called the Stress Memorization Technique. This technique requires four additional steps with respect to conventional processing (FIGS. 1d-1g). Nevertheless, this Stress Memorization Technique might be introduced for advanced CMOS technologies for the transistors. In this case the silicided polysilicon fuse could benefit from the strain engineering performed in that technology and fewer or no extra steps would be needed.

Referring to FIGS. 2a-2f, these Figures illustrate a second method of manufacturing a fuse structure according to the invention. The first stages of the method as illustrated by FIGS. 2a-2c are exactly the same as for the first method.

FIG. 2d refers to a further stage of the second method. In that stage spacers 9 are formed on sidewalls of the fuse body similar to the first method. In yet a further stage of the second method (FIG. 2e) a silicide 11 is formed on the fuse body FB similar to the first method. In a further stage of the second method a tensile strain layer 7 is provided covering both the fuse body FB, the spacers 9 and the field oxide region 9. The strain layer 7 induces a compressive strain in a vertical direction Z perpendicular to the substrate 1 and a tensile strain in the current flow direction CF. In other words, the polysilicon PLY changes into strained polysilicon PLYS. The strain in the fuse body FB is beneficial to the electron mobility. The strain layer 7 is preferably a high-tensile strain layer comprising a nitride. In that case the implementation requires only additional step with respect to conventional processing. Furthermore, the nitride layer can act as a contact etch-stop layer (CESL). The technique illustrated in FIGS. 2a to 2f is also called the nitride stressor approach. This technique might be introduced in advanced CMOS technologies for the transistors. In that case, just like the first method, the silicided polysilicon fuse could benefit from the strain engineering already performed in that technology and fewer or no extra steps would be needed.

Referring to FIG. 3, this Figure illustrates a schematic cross-section of a silicided polysilicon fuse structure having a contact. This silicided polysilicon fuse structure F has been manufactured with the second method according to the invention. It is important that in the fuse structure according to the invention at least the fuse body is strained. It must be noted the designer is free to implement the strain layer 7 not only on the fuse body, but also on the contact areas of the fuse structure F, because covering the fuse contact areas is not detrimental to the operation of the fuse structure F. The strain layer 7 is still present in the fuse structure in FIG. 3. In case the strain layer 7 has been provided over the complete fuse structure F, it can be used as a contact etch-stop layer (CESL) during manufacturing of the contact CO. The contact can be made of tungsten for example, but other materials are also possible. The contact CO connects the strained polysilicon layer material PLYS of the fuse structure F to the first interconnect layer M1. This interconnect layer M1 may comprise aluminum for example.

Referring to FIG. 4, this Figure illustrates two different shapes of the fuse structure according to the invention. The FIG. 4 only illustrates the layer comprising polysilicon 5. All other layers have been left out for simplicity. The upper fuse structure 20 in FIG. 4 illustrates a fuse structure having a straight fuse body FB and square/rectangular fuse heads FH. The lower fuse structure 30 in FIG. 4 illustrates a fuse structure having a straight fuse body FB and tapered fuse heads FH. The contact regions (not shown) of the fuse structures 20,30 are normally located on the fuse heads FH. In the current fuse structure examples in FIG. 4 the fuse bodies FB are straight, but they may also comprise bends, notches, holes, etc. in order to enhance their performance. All these variations fall under the scope of the invention being defined by the claims.

Fusing is well known by the person skilled in the art. Various publications on this matter exist. During the programming of a semiconductor polysilicon fuse the resistance increases from a first low level to a second higher level. This difference in resistance can be detected such that for example a programmable memory can be made. The physical phenomena, which occur during heavy programming, depend on various conditions. A recent publication, which explains the fusing mechanisms the best, is T. S. Doom, M. Altheimer, “Ultra-fast programming of silicided polysilicon fuses based on new insights in the programming physics”, IEDM Techn. Digest, pp. 667-670, 2005.

This invention improves upon the known fuse structures because it enhances the electron mobility in the fuse body by means of strain. Because of this measure the fuse will either be programmed faster at the same programming voltage, or be programmed at a lower programming voltage in the same programming time.

The invention thus provides an attractive semiconductor fuse structure having a better performance than the known fuse structures.

The invention also provides methods of manufacturing such fuse structures.

Throughout the specification the use of polysilicon material in the fuse body has been mentioned. However, the skilled person may be able to find alternative materials later on, which are also suitable for semiconductor fuse structures. Therefore, these kind of variations have to be regarded as equivalents to polysilicon and do not depart from the scope of the invention which is defined by the claims.

The present invention has been described with respect to particular embodiments and with reference to certain drawings, but the invention is not limited thereto but only by the claims. Any reference signs in the claims shall not be construed as limiting the scope. The drawings described are only schematic and are non-limiting. In the drawings, the size of some of the elements may be exaggerated and not drawn to scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used to distinguish between similar elements and not necessarily to describe a sequential or chronological order. It is to be understood that the terms so used are interchangeable under appropriate circumstances and that the embodiments of the invention described herein are capable of operation in other sequences than described or illustrated herein.

1. A semiconductor fuse structure comprising a substrate having a surface, the substrate having a field oxide region at the surface, the fuse structure further comprising a fuse body, the fuse body comprising polysilicon, the fuse body lying over the field oxide region and extending into a current-flow direction, wherein the fuse structure is programmable by means of leading a current through the fuse body, characterized in that the fuse body has a tensile strain in the current-flow direction and a compressive strain in a direction perpendicular to said surface of the substrate.

2. A semiconductor fuse structure as claimed in claim 1, characterized in that the fuse body comprises a first sublayer and a second sublayer, the first sublayer comprising polysilicon, the first sublayer lying over the field oxide region, the second sublayer comprising a silicide, the second sublayer lying over the first sublayer.

3. A semiconductor fuse structure as claimed in claim 1, characterized in that a tensile-strain layer at least covers both the fuse body and part of the substrate, for forming the compressive strain in the fuse body in the direction perpendicular to said surface.

4. An integrated circuit comprising a semiconductor fuse structure as claimed in claim 1.

5. A method of manufacturing a fuse structure having a fuse body, the method comprising:
providing a substrate having a surface, the substrate comprising a field oxide region at the surface;
providing a first layer comprising polysilicon at least in the field oxide region;
patterning the first layer for at least forming a fuse body in the field oxide region, the fuse body extending into a current-flow direction;
performing an amorphization implant on the first layer for converting the polysilicon of at least the fuse body into amorphous silicon;
covering the substrate and the fuse body with a strain layer, wherein the strain layer is a low-strain or tensile-strain layer which results in a compressive strain in the fuse body in a direction perpendicular to the surface and which further results in a tensile strain in the fuse body in the current-flow direction;
performing a spike-anneal such that the amorphous silicon in providing spacers on both sidewalls of the fuse body;

6. A method of manufacturing a fuse structure as claimed in claim 5, characterized in that before providing spacers, the strain layer is removed.

7. A method of manufacturing a fuse structure as claimed in claim 5, characterized in that the method comprises a step of forming a silicide on the fuse body prior to the step of covering the substrate and the fuse body with a strain layer or after removal of the strain layer.

8. A method of manufacturing a fuse structure comprising a fuse body, the method comprising:
providing a substrate having a surface, the substrate comprising a field oxide region at the surface;
providing a first layer comprising polysilicon at least in the field oxide region;
patterning the first layer for at least forming a fuse body in the field oxide region, the fuse body extending into a current-flow direction;
providing spacers on both sidewalls of the fuse body; and
covering the substrate, the fuse body and the spacers with a strain layer, wherein the strain layer is a tensile strain layer which results in a compressive strain in the fuse body in a direction perpendicular to the surface and which further results in a tensile strain in the fuse body in the current-flow direction.

9. A method of manufacturing a fuse structure as claimed in claim 8, characterized in that the method further comprises forming a silicide on the fuse body, prior to the step of covering the substrate, the fuse body and the spacers with the strain layer.
